(19) United States
(12) Patent Application Publication
(10) Pub. No.: US 2023/0327066 A1
(43) Pub. Date: Oct. 12, 2023

(54) ALL-SOLID-STATE BATTERY COMPRISING ANODE CURRENT COLLECTOR WITH ALLOY LAYER AND METHOD FOR MANUFACTURING THE SAME

(71) Applicants: HYUNDAI MOTOR COMPANY, Seoul (KR); KIA CORPORATION, Seoul (KR)

(72) Inventors: Ju Min Kim, Hwaseong-si (KR); Seung Ho Choi, Hanam-si (KR); Tae Young Kwon, Daegu (KR); Soon Chul Byun, Yongin-si (KR)

(73) Assignees: Hyundai Motor Company, Seoul (KR); Kia Corporation, Seoul (KR)

(21) Appl. No.: 17/989,264

(22) Filed: Nov. 17, 2022

(30) Foreign Application Priority Data
Apr. 11, 2022 (KR) 10-2022-0044291

(51) Int. Cl. H01M 4/04; H01M 4/38

(52) U.S. Cl. CPC H01M 4/0404; H01M 4/0426; H01M 4/38

(57) ABSTRACT

Disclosed are an all-solid-state battery which is provided with an intermediate layer provided on an anode current collector and formed of an alloy including a metal configured to form an alloy with lithium, and a method for manufacturing the same. The all-solid-state battery includes the anode current collector, the intermediate layer located on the anode current collector, a solid electrolyte layer located on the intermediate layer, a cathode active material layer located on the solid electrolyte layer, and a cathode current collector located on the cathode active material layer, and the intermediate layer includes the alloy of a first metal configured to form an alloy with lithium and a second metal configured not to form an alloy with lithium.

### CROSS-REFERENCE TO RELATED APPLICATION

This application claims under 35 U.S.C. §119(a) the benefit of priority to Korean Patent Application No. 10-2022-0044291 filed on Apr. 11, 2022 in the Korean Intellectual Property Office, the entire contents of which are incorporated herein by reference.

### TECHNICAL FIELD

The present disclosure relates to an all-solid-state battery which is provided with an intermediate layer disposed on an anode current collector, and a method for manufacturing the same.

### BACKGROUND

Recently, as the need for a battery having high energy density and excellent stability arises, all-solid-state batteries are being vigorously researched. An all-solid-state battery includes a cathode active material layer, an anode active material layer, and a solid electrolyte layer located between the cathode active material layer and the anode active material layer, and all materials used in the all-solid-state battery are solid.

In order to increase energy density, an anodeless all-solid-state battery, which does not include an anode active material, has been proposed recently.

In the anodeless all-solid-state battery, lithium ions coming from a cathode active material are stored in the form of lithium metal on the surface of an anode current collector during charging. That is, although the anodeless all-solid-state battery does not include any anode active material, lithium ions may be stored. In order to reversibly charge and discharge the anodeless all-solid-state battery, lithium ions should be uniformly converted into lithium metal on the surface of the anode current collector, and growth of lithium dendrites should be suppressed during the charging process of the anodeless all-solid-state battery.

The anode current collector includes a material which has high electrical conductivity and does not react with a solid electrolyte, such as nickel or copper. However, most materials used to form the anode current collector have poor lithium affinity, and thus, when they are applied to the anodeless all-solid-state battery, lithium metal is non-uniformly deposited on the surface of the anode current collector.

In order to solve such a problem, research on coating the surface of the anode current collector with noble metals having lithium affinity is being carried out. Noble metals, such as silver (Ag), platinum (Pt) and gold (Au), may easily react with lithium ions so as to form lithium alloys, and may induce deposition of lithium metal in the horizontal direction along the surface of the anode current collector. However, as an alloy of lithium and a noble metal is formed and decomposed during the charging and discharging process, the volume of a coating layer is expanded and contracted, and fine cracks may occur in the coating layer. This reduces long-term cycle efficiency. Further, noble metals, such as silver (Ag), platinum (Pt) and gold (Au), are expensive, and thus cause rise in raw material prices.

The above information disclosed in this Background section is only for enhancement of understanding of the background of the disclosure and therefore it may contain information that does not form the prior art that is already known in this country to a person of ordinary skill in the art.

### SUMMARY OF THE DISCLOSURE

The present disclosure has been made in an effort to solve the above-described problems associated with the prior art, and it is an object of the present disclosure to provide an all-solid-state battery in which lithium metal may be uniformly deposited during charging, and a method for manufacturing the same.

It is another object of the present disclosure to provide an all-solid-state battery which may relieve volume expansion due to deposition of lithium metal, and a method for manufacturing the same.

It is yet another object of the present disclosure to provide an all-solid-state battery which may secure price competitiveness through cost reduction, and a method for manufacturing the same.

In one aspect, the present disclosure may provide an all-solid-state battery including an anode current collector, an intermediate layer disposed on the anode current collector, a solid electrolyte layer disposed on the intermediate layer, a cathode active material layer disposed on the solid electrolyte layer, and a cathode current collector disposed on the cathode active material layer, wherein the intermediate layer may include an alloy of a first metal capable of alloying with lithium and a second metal incapable of alloying with lithium.

In a preferred embodiment, the intermediate layer may have no grains.

In another preferred embodiment, the first metal may include at least one selected from the group consisting of silver (Ag), gold (Au), platinum (Pt), palladium (Pd), and combinations thereof.

In still another preferred embodiment, the second metal may include at least one selected from the group consisting of nickel (Ni), titanium (Ti), manganese (Mn), iron (Fe), cobalt (Co), and combinations thereof.

In yet another preferred embodiment, the intermediate layer may include an amount of about greater than 50% by weight and 90% by weight or less of the first metal; and an amount of about 10% by weight or more and less than 50% by weight of the second metal.

In still yet another preferred embodiment, a thickness of the intermediate layer may be about 100 nm to 1,000 nm.

In another aspect, the present disclosure may provide a method for manufacturing an all-solid-state battery including forming an intermediate layer including an alloy of a first metal capable of alloying with lithium and a second metal incapable of alloying with lithium on an anode current collector by simultaneously sputtering a first target including the first metal and a second target including the second metal, and manufacturing a stack including a solid electrolyte layer disposed on the intermediate layer, a cathode active material layer disposed on the solid electrolyte layer, and a cathode current collector disposed on the cathode active material layer.

Other aspects and preferred embodiments of the disclosure are discussed infra.

The above and other features of the disclosure are discussed infra.

### BRIEF DESCRIPTION OF THE DRAWINGS

The above and other features of the present disclosure will now be described in detail with reference to certain exemplary embodiments thereof illustrated in the accompanying drawings which are given hereinbelow by way of illustration only, and thus are not limitative of the present disclosure, and wherein:

FIG. 1 shows a cross-sectional view of an all-solid-state battery according to the present disclosure;

FIG. 2 shows a cross-sectional view of the state in which the all-solid-state battery according to the present disclosure is initially charged;

FIG. 3 shows a cross-sectional view of the state in which the all-solid-state battery according to the present disclosure is fully charged;

FIG. 4A shows Scanning Electron Microscopy with Energy Dispersive X-ray Spectroscopy (SEM-EDS) analysis results of the surface of an intermediate layer according to Example 1;

FIG. 4B shows SEM-EDS analysis results of the surface of an intermediate layer according to Example 2;

FIG. 4C shows SEM-EDS analysis results of the surface of an intermediate layer according to Comparative Example 1;

FIG. 5 shows lifespans of half-cells according to Example 1 and Comparative Example 1;

FIG. 6A shows the first charge and discharge cycles of half-cells according to Example 2 and Comparative Example 2;

FIG. 6B shows lifespans of the half-cells according to Example 2 and Comparative Example 2;

FIG. 6C shows coulombic efficiencies of the half-cells according to Example 2 and Comparative Example 2 per cycle;

FIG. 7 shows SEM-EDS analysis results of the surface of an intermediate layer according to Example 3; and

FIG. 8 shows a reversible capacity of a half-cell according to Example 3.

It should be understood that the appended drawings are not necessarily to scale, presenting a somewhat simplified representation of various preferred features illustrative of the basic principles of the disclosure. The specific design features of the present disclosure as disclosed herein, including, for example, specific dimensions, orientations, locations, and shapes, will be determined in part by the particular intended application and use environment.

In the figures, reference numbers refer to the same or equivalent parts of the present disclosure throughout the several figures of the drawing.

### DETAILED DESCRIPTION

The above-described objects, other objects, advantages and features of the present disclosure will become apparent from the descriptions of embodiments given herein below with reference to the accompanying drawings. However, the present disclosure is not limited to the embodiments disclosed herein and may be implemented in various different forms. The embodiments are provided to make the description of the present disclosure thorough and to fully convey the scope of the present disclosure to those skilled in the art.

In the following description of the embodiments, the same elements are denoted by the same reference numerals even when they are depicted in different drawings. In the drawings, the dimensions of structures may be exaggerated compared to the actual dimensions thereof, for clarity of description. In the following description of the embodiments, terms, such as “first” and “second”, may be used to describe various elements but do not limit the elements. These terms are used only to distinguish one element from other elements. For example, a first element may be named a second element, and similarly, a second element may be named a first element, without departing from the scope and spirit of the disclosure. Singular expressions may encompass plural expressions, unless they have clearly different contextual meanings.

In the following description of the embodiments, terms, such as “including”, “comprising” and “having”, are to be interpreted as indicating the presence of characteristics, numbers, steps, operations, elements or parts stated in the description or combinations thereof, and do not exclude the presence of one or more other characteristics, numbers, steps, operations, elements, parts or combinations thereof, or possibility of adding the same. In addition, it will be understood that, when a part, such as a layer, a film, a region or a plate, is said to be “on” another part, the part may be located “directly on” the other part or other parts may be interposed between the two parts. In the same manner, it will be understood that, when a part, such as a layer, a film, a region or a plate, is said to be “under” another part, the part may be located “directly under” the other part or other parts may be interposed between the two parts.

All numbers, values and/or expressions representing amounts of components, reaction conditions, polymer compositions and blends used in the description are approximations in which various uncertainties in measurement generated when these values are acquired from essentially different things are reflected and thus it will be understood that they are modified by the term “about”, unless stated otherwise. As used herein, the term “about” means modifying, for example, lengths, degrees of errors, dimensions, the quantity of an ingredient in a composition, concentrations, volumes, process temperature, process time, yields, flow rates, pressures, and like values, and ranges thereof, refers to variation in the numerical quantity that may occur, for example, through typical measuring and handling procedures used for making compounds, compositions, concentrates or use formulations; through inadvertent error in these procedures; through differences in the manufacture, source, or purity of starting materials or ingredients used to carry out the methods; and like considerations. Whether modified by the term “about” the claims appended hereto include equivalents to these quantities. The term “about” further may refer to a range of values that are similar to the stated reference value. In certain embodiments, the term “about” refers to a range of values that fall within 10, 9, 8,7, 6, 5,4, 3, 2, 1 percent above or below the numerical value (except where such number would exceed 100% of a possible value or go below 0%) or a plus/minus manufacturing/measurement tolerance of the numerical value. In addition, it will be understood that, if a numerical range is disclosed in the description, such a range includes all continuous values from a minimum value to a maximum value of the range, unless stated otherwise. Further, if such a range refers to integers, the range includes all integers from a minimum integer to a maximum integer, unless stated otherwise.

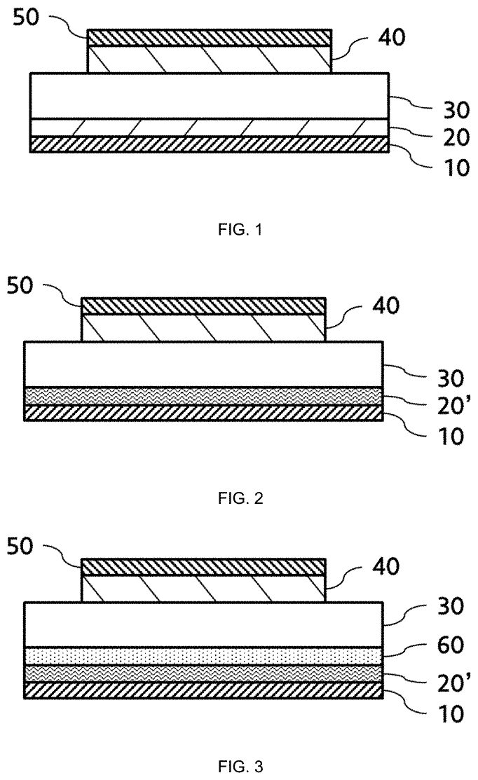

FIG. 1 shows a cross-sectional view of an all-solid-state battery according to the present disclosure. The all-solid-state battery may include an anode current collector 10, an intermediate layer 20 disposed on the anode current collector 10, a solid electrolyte layer 30 disposed on the intermediate layer 20, a cathode active material layer 40 disposed on the solid electrolyte layer 30 and including a cathode active material, and a cathode current collector 50 disposed on the cathode active material layer 40.

The intermediate layer 20 may include an alloy of a first metal capable of alloying with lithium and a second metal incapable of alloying with lithium.

FIG. 2 shows a cross-sectional view of the state in which the all-solid-state battery according to the present disclosure is initially charged. At the initial stage of charging, lithium ions coming from the cathode active material migrate to the intermediate layer 20 through the solid electrolyte layer 30, and then contact and react with the alloy of the intermediate layer 20, thus forming an alloy layer 20′. The alloy has lithium affinity caused by the first metal, and may thus react with lithium ions. Here, the second metal suppresses expansion of the volume of the alloy layer 20′.

FIG. 3 shows a cross-sectional view of the state in which the all-solid-state battery according to the present disclosure is fully charged. As the reaction between the alloy and the lithium ions progresses, a lithium layer 60 is formed on the alloy layer 20′.

As such, among the alloy forming the intermediate layer 20, the first metal may react with lithium ions so that lithium may be deposited thereon, and the second metal may suppress volume expansion due to deposition of lithium.

The first metal may include a noble metal which may form an alloy with lithium, and may include at least one selected from the group consisting of silver (Ag), gold (Au), platinum (Pt), palladium (Pd), and combinations thereof.

The second metal may include a transition metal which does not form an alloy with lithium, and may include at least one selected from the group consisting of nickel (Ni), titanium (Ti), manganese (Mn), iron (Fe), cobalt (Co), and combinations thereof.

The intermediate layer 20 may include an amount of about greater than 50% by weight and 90% by weight or less of the first metal; and an amount of about 10% by weight or more and less than 50% by weight of the second metal. When the content of the second metal is 50% by weight or more, the second metal may suppress the reaction between lithium ions and the first metal so that lithium may not be uniformly deposited. During charging, lithium ions migrate toward the first metal which may react with lithium, and thus, the alloy forming the intermediate layer 20 may include a major amount of the first metal.

The thickness of the intermediate layer 20 may be about 100 nm to 1,000 nm. When the thickness of the intermediate layer 20 is less than 100 nm, the interface between the intermediate layer 20 and the solid electrolyte layer 30 may not be uniformly formed. On the other hand, when the thickness of the intermediate layer 20 exceeds 1,000 nm, a time taken to manufacture the intermediate layer 20 may be lengthened, and thus, productivity of the intermediate layer 20 may be reduced.

The intermediate layer 20 may be uniformly formed without grains. The reason for this is that the intermediate layer 20 is formed by thermal sputtering. This will be described later.

The anode current collector 10 may be a plate-shaped base material having electrical conductivity. The anode current collector 10 may be provided in the form of a sheet, a thin film or a foil.

The anode current collector 10 may include a material which does not react with lithium. The anode current collector 10 may include at least one selected from the group consisting of nickel (Ni), copper (Cu), stainless steel (SUS), and combinations thereof.

The solid electrolyte layer 30 may be interposed between the cathode active material layer 40 and the anode current collector 10, and may conduct lithium ions.

The solid electrolyte layer 30 may include a solid electrolyte having lithium ion conductivity.

The solid electrolyte may include at least one selected from the group consisting of oxide-based solid electrolytes, sulfide-based solid electrolytes, polymer solid electrolytes, and combinations thereof. Preferably, a sulfide-based solid electrolyte having high lithium ion conductivity may be used. The sulfide-based solid electrolytes may include Li₂S—P₂S₅, Li₂S—P₂S₅—Lil, Li₂S—P₂S₅—LiCl, Li₂S—P₂S₅—LiBr, Li₂S—P₂S₅—Li₂O, Li₂S—P₂S₅—Li₂O—Lil, Li₂S—SiS₂, Li₂S—SiS₂—Lil, Li₂S—SiS₂—LiBr, Li₂S—SiS₂—LiCl, Li₂S—SiS₂—B₂S₃—Lil, Li₂S—SiS₂—P₂S₅—Lil, Li₂S—B₂S₃, Li₂S—P₂S₅—ZmSn (m and n being positive numbers, and Z being one of Ge, Zn and Ga), Li₂S—GeS₂, Li₂S—SiS₂—Li₃PO₄, Li₂S—SiS₂—LiₓMO_{y} (x and y being positive numbers, and M being one of P, Si, Ge, B, Al, Ga and In), and Li₁₀GeP₂S₁₂, without being limited thereto.

The oxide-based solid electrolytes may include perovskite-type LLTO (Li₃ₓLa_{2/3-x}TiO₃), phosphate-based NASICON-type LATP(Li₁₊ₓAlₓTi₂₋ₓ(PO₄)₃), etc.

The polymer electrolytes may include gel polymer electrolytes, solid polymer electrolytes, etc.

The cathode active material layer 40 may include a cathode active material capable of intercalating and deintercalating lithium ions, a solid electrolyte, a conductive material, a binder, etc.

The cathode active material may include an oxide active material or a sulfide active material.

The oxide active material may include a rock salt layer-type active material, such as LiCoO₂, LiMnO₂, LiNiO₂, LiVO₂ or Li_{1-30 x}Ni_{1/3}Co_{1/3}Mn_{1/3}O₂, a spinel-type active material, such as LiMn₂O₄ or Li(Ni_{0.5}Mn_{1.5})O₄, an inverted spinel-type active material, such as LiNiVO₄ or LiCoVO₄, an olivine-type active material, such as LiFePO₄, LiMnPO₄, LiCoPO₄ or LiNiPO₄, a silicon-containing active material, such as Li₂FeSiO₄ or Li₂MnSiO₄, a rock salt layer-type active material in which a part of a transition metal is substituted with a different kind of metal, such as LiNi_{0.8}Co_{(0.2-x)}AlₓO₂ (0<x<0.2), a spinel-type active material in which a part of a transition metal is substituted with a different kind of metal, such as Li₁₊ₓMn_{2-x-y}M_{y}O₄ (M being at least one of Al, Mg, Co, Fe, Ni or Zn, and 0<x+y<2), or lithium titanate, such as Li₄Ti₅O₁₂.

The sulfide active material may include copper Chevrel, iron sulfide, cobalt sulfide, nickel sulfide or the like.

The solid electrolyte may include an oxide-based solid electrolyte or a sulfide-based solid electrolyte. Preferably, a sulfide-based solid electrolyte having high lithium ion conductivity may be used. The sulfide-based solid electrolyte may include Li₂S—P₂S₅, Li₂S—P₂S₅—Lil, Li₂S—P₂S₅—LiCl, Li₂S—P₂S₅—LiBr, Li₂S—P₂S₅—Li₂O, Li₂S—P₂S₅—Li₂O—Lil, Li₂S—SiS₂, Li₂S—Si_{S}2—Lil, Li₂S—SiS₂—LiBr, Li₂S—SiS₂—LiCl, Li₂S—SiS₂—B₂S₃—Lil, Li₂S—SiS₂—P₂S₅—Lil, Li₂S—B₂S₃, Li₂S—P₂S₅—ZmSn (m and n being positive numbers, and Z being one of Ge, Zn and Ga), Li₂S—GeS₂, Li₂S—SiS₂—Li₃PO₄, Li₂S—SiS₂—LiₓMO_{y} (x and y being positive numbers, and M being one of P, Si, Ge, B, Al, Ga and In), or Li₁₀GeP₂S₁₂, without being limited thereto.

The conductive material may include carbon black, conductive graphite, ethylene black, carbon fiber, graphene or the like.

The binder may include butadiene rubber (BR), nitrile butadiene rubber (NBR), hydrogenated nitrile butadiene rubber (HNBR), polyvinylidene difluoride (PVDF), polytetrafluoroethylene (PTFE), carboxymethyl cellulose (CMC) or the like.

The cathode current collector 50 may be a plate-shaped base material having electrical conductivity. The cathode current collector 50 may include an aluminum foil.

A method for manufacturing an all-solid-state battery according to the present disclosure may include forming an intermediate layer including an alloy of a first metal capable of alloying with lithium and a second metal incapable of alloying with lithium on an anode current collector by simultaneously sputtering a first target including the first metal and a second target including the second metal, and manufacturing a stack including a solid electrolyte layer disposed on the intermediate layer, a cathode active material layer disposed on the solid electrolyte layer, and a cathode current collector disposed on the cathode active material layer.

The intermediate layer may be formed by simultaneously sputtering the first target including the first metal and the second target including the second metal in a chamber of sputtering equipment. Therethrough, the contents of the first metal and the second metal may be minutely adjusted, and the intermediate layer may be uniformly formed without growth of grains.

Sputtering is not limited to a specific method and, for example, the intermediate layer may be formed by thermal sputtering, magnetron sputtering or the like.

The first target may be sputtered at the output of about 50W to 120W and the second target may be sputtered at the output of about 55W to 220W based on the anode current collector having an area of about 10×10 cm⁻². Further, base pressure may be about 10⁻⁷ mtorr, and working pressure may be adjusted to about 1 mtorr to 5 mtorr by injecting Ar gas into the chamber. The flow rate of Ar gas may be about 10 scc/min to 20 scc/min, and a deposition temperature may be about 25° C. to 30° C.

Formation of the stack is not limited to a specific method. The respective components may be formed at the same time or at different times. For example, the above-described method for manufacturing the all-solid-state battery may be executed by forming the solid electrolyte layer, the cathode active material layer and the cathode current collector directly on the intermediate layer, as described above, or may be executed by separately preparing the respective elements and then stacking the respective elements into the structure shown in FIG. 1.

Hereinafter, the present disclosure will be described in more detail through the following examples. The following examples serve merely to exemplarily describe the present disclosure, and are not intended to limit the scope of the disclosure.

### EXAMPLE 1

An anode current collector including stainless steel (SUS) was prepared. An intermediate layer including an alloy of silver (Ag) and nickel (Ni) was formed on the anode current collector by thermally sputtering a first target including silver (Ag) as a first metal and a second target including nickel (Ni) as a second metal, simultaneously. The alloy includes about 90% by weight of silver (Ag) and about 10% by weight of nickel (Ni). The thickness of the intermediate layer was about 500 nm.

### EXAMPLE 2

An intermediate layer was formed on an anode current collector in the same manner as in Example 1, except that an alloy includes about 70% by weight of silver (Ag) and about 30% by weight of nickel (Ni).

### COMPARATIVE EXAMPLE 1

An intermediate layer was formed on an anode current collector in the same manner as in Example 1, except that an alloy includes about 50% by weight of silver (Ag) and about 50% by weight of nickel (Ni).

### COMPARATIVE EXAMPLE 2

An anode current collector including stainless steel (SUS) was prepared.

An intermediate layer formed of silver (Ag) alone was formed on the anode current collector by thermally sputtering a target including silver (Ag) as a first metal.

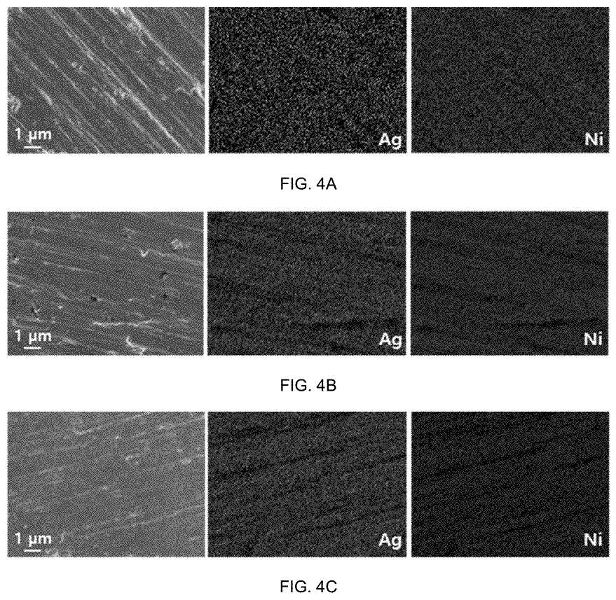

FIG. 4A shows Scanning Electron Microscopy with Energy Dispersive X-ray Spectroscopy (SEM-EDS) analysis results of the surface of the intermediate layer according to Example 1. FIG. 4B shows SEM-EDS analysis results of the surface of the intermediate layer according to Example 2. FIG. 4C shows SEM-EDS analysis results of the surface of the intermediate layer according to Comparative Example 1. Referring to FIGS. 4A to 4C, it may be confirmed that the intermediate layer was formed in a smooth shape on the anode current collector regardless of the ratio of silver (Ag) to nickel (Ni). Further, it may be confirmed that grains were not formed by simultaneously sputtering the first metal and the second metal. According to the SEM-EDS analysis results, silver (Ag) and nickel (Ni) are uniformly distributed.

### TEST EXAMPLE 1

Half-cells for evaluation including a lithium metal layer, a solid electrolyte layer, an intermediate layer, and an anode current collector were manufactured using the anode current collectors having the intermediate layers according to Example 1 and Comparative Example 1. In order to manufacture each of the half-cells, about 0.15 g of solid electrolyte powder was fed into a polymer mold having an inner diameter of 13 φ. The solid electrolyte layer was manufactured by pressing the solid electrolyte powder at a pressure of about 100 MPa for 1 minute. The corresponding anode current collector was located on one surface of the solid electrolyte layer such that the intermediate layer comes into contact with the solid electrolyte layer, and was pressed at a pressure of about 450 MPa for 1 minute. A lithium foil having a thickness of about 200 μm to the other surface of the solid electrolyte layer, and was pressed at a pressure of about 30 MPa. Thereby, the half-cells were manufactured.

Here, in order to evaluate characteristics of the half-cells, a current density was 1.17 mA/cm², a deposition capacity was 3.52 mAh/cm², and a driving temperature was 30° C.

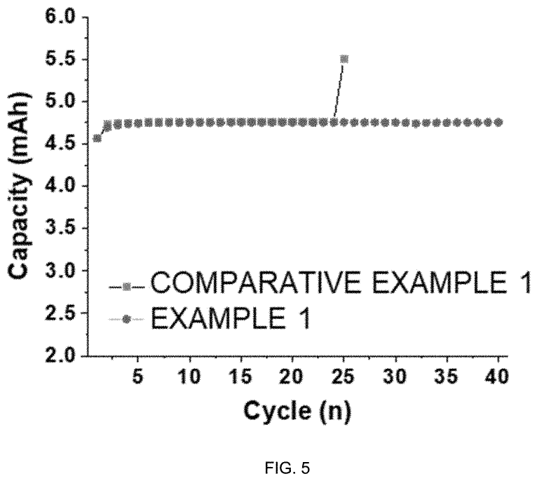

FIG. 5 shows lifespans of the half-cells according to Example 1 and Comparative Example 1. Both half-cells were reversibly driven, and short circuit occurred in the half-cell according to Comparative Example 1 in the 25th cycle. It may be supposed that the content of the second metal is excessively high and thus suppresses reaction between lithium ions and the first metal.

### TEST EXAMPLE 2

Half-cells having the same structure as in Test Example 1 were manufactured using the anode current collectors having the intermediate layers according to Example 2 and Comparative Example 2. Conditions for evaluating characteristics of the half-cells were the same as the conditions in Test Example 1.

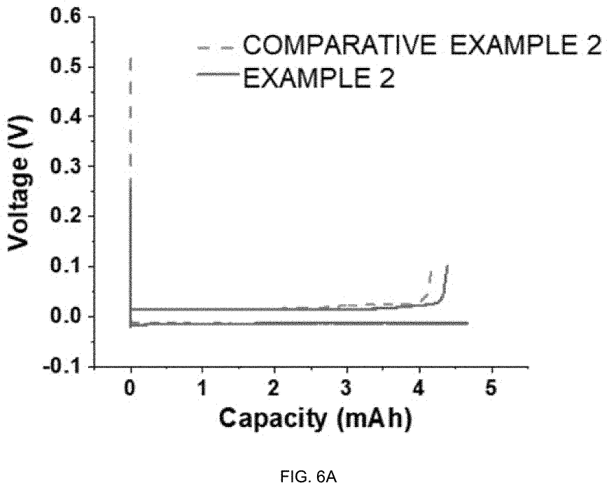

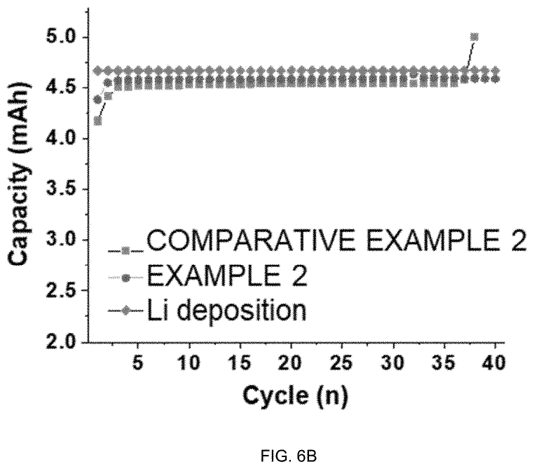

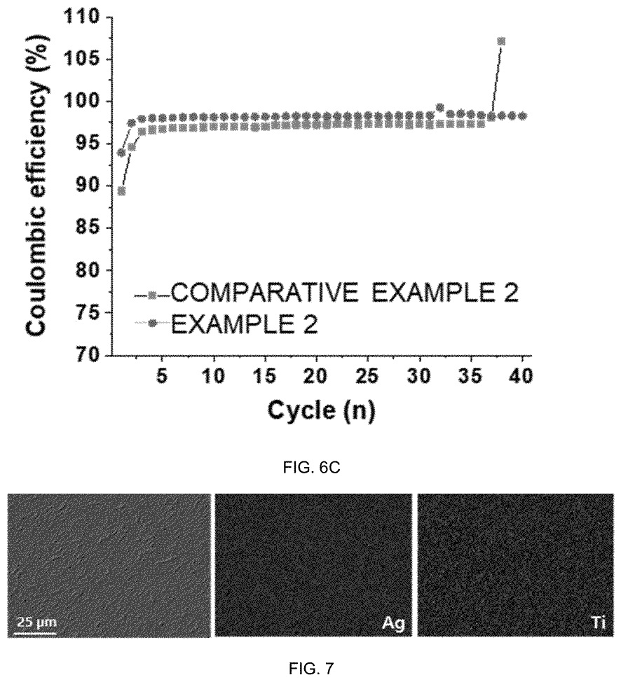

FIG. 6A shows the first charge and discharge cycles of the half-cells according to Example 2 and Comparative Example 2. Nucleation energy related to lithium deposition was not observed in both the half-cells at the initial stage of a lithium deposition process around a capacity of 0.01 mAh. This means that silver (Ag) existing in the alloy may reduce nucleation energy related to lithium deposition. Both the half-cells exhibit overvoltage during the lithium deposition and dissolution processes. This means that, even though an alloy other than a noble metal is used as the intermediate layer as in the present disclosure, the resistance of a battery does not increase.

FIG. 6B shows lifespans of the half-cells according to Example 2 and Comparative Example 2. The half-cell according to Comparative Example 2 exhibits a low reversible capacity per cycle starting from the first cycle, as compared to the half-cell according to Example 2. Further, short circuit occurred in the half-cell according to Comparative Example 2 in the 37th cycle. This is caused by volume expansion of silver (Ag), which is a noble metal, during the lithium deposition process.

FIG. 6C shows coulombic efficiencies of the half-cells according to Example 2 and Comparative Example 2 per cycle. In the half-cell according to Example 2, initial Coulombic efficiency was 93%, and Coulombic efficiency per cycle was 98% or more. On the other hand, in the half-cell according to Comparative Example 2, initial Coulombic efficiency was 89%, and Coulombic efficiency per cycle was 96%. This means that the alloy is more suitable for reversible storage and dissolution of lithium during the charging and discharging process.

### EXAMPLE 3

An intermediate layer was formed on an anode current collector in the same manner as in Example 2, except that titanium (Ti) was used as a second metal.

FIG. 7 shows SEM-EDS analysis results of the surface of the intermediate layer according to Example 3. It may be confirmed that, although silver (Ag) and titanium (Ti) were used, the intermediate layer having a smooth surface was formed without growth of grains. Further, as the SEM-EDS analysis results, silver (Ag) and titanium (Ti) were uniformly detected.

A half-cell having the same structure as in Test Example 1 was manufactured using the anode current collector having the intermediate layer according to Example 3. Conditions for evaluating characteristics of the half-cell were the same as the conditions in Test Example 1.

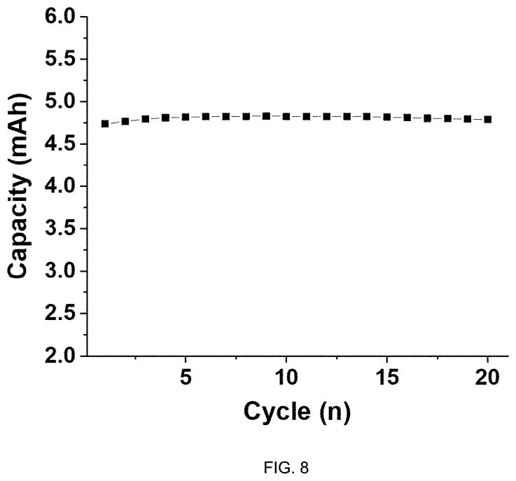

FIG. 8 shows a reversible capacity of the half-cell according to Example 3 per cycle. It may be confirmed that the half-cell was stably driven during 20 cycles.

As is apparent from the above description, the present disclosure may provide an all-solid-state battery in which lithium metal may be uniformly deposited during charging, and a method for manufacturing the same.

Further, the present disclosure may provide an all-solid-state battery which may relieve volume expansion due to deposition of lithium metal, and a method for manufacturing the same.

In addition, the present disclosure may provide an all-solid-state battery which may secure price competitiveness through cost reduction, and a method for manufacturing the same.

The disclosure has been described in detail with reference to preferred embodiments thereof. However, it will be appreciated by those skilled in the art that changes may be made in these embodiments without departing from the principles and spirit of the disclosure, the scope of which is defined in the appended claims and their equivalents.

What is claimed is:

1. An all-solid-state battery comprising:
an anode current collector;
an intermediate layer disposed on the anode current collector;
a solid electrolyte layer disposed on the intermediate layer;
a cathode active material layer disposed on the solid electrolyte layer; and
a cathode current collector disposed on the cathode active material layer,
wherein the intermediate layer comprises an alloy of a first metal capable of alloying with lithium and a second metal incapable of alloying with lithium.

2. The all-solid-state battery of claim 1, wherein the intermediate layer has no grains.

3. The all-solid-state battery of claim 1, wherein the first metal comprises at least one of silver (Ag), gold (Au), platinum (Pt), palladium (Pd), or any combination thereof.

4. The all-solid-state battery of claim 1, wherein the second metal comprises at least one of nickel (Ni), titanium (Ti), manganese (Mn), iron (Fe), cobalt (Co), or any combination thereof.

5. The all-solid-state battery of claim 1, wherein the intermediate layer comprises:
an amount of about greater than 50% by weight and 90% by weight or less of the first metal; and
an amount of about 10% by weight or more and less than 50% by weight of the second metal.

6. The all-solid-state battery of claim 1, wherein a thickness of the intermediate layer is about 100 nm to 1,000 nm.

7. A method for manufacturing an all-solid-state battery, comprising:
forming an intermediate layer comprising an alloy of a first metal capable of alloying with lithium and a second metal incapable of alloying with lithium on an anode current collector by simultaneously sputtering a first target comprising the first metal and a second target comprising the second metal; and
manufacturing a stack comprising a solid electrolyte layer disposed on the intermediate layer, a cathode active material layer disposed on the solid electrolyte layer, and a cathode current collector disposed on the cathode active material layer.

8. The method of claim 7, wherein the intermediate layer has no grains.

9. The method of claim 7, wherein the first metal comprises at least one of silver (Ag), gold (Au), platinum (Pt), palladium (Pd), or any combination thereof.

10. The method of claim 7, wherein the second metal comprises at least one of nickel (Ni), titanium (Ti), manganese (Mn), iron (Fe), cobalt (Co), or any combination thereof.

11. The method of claim 7, wherein the intermediate layer comprises:
an amount of about greater than 50% by weight and 90% by weight or less of the first metal; and
an amount of about 10% by weight or more and less than 50% by weight of the second metal.

12. The method of claim 7, wherein a thickness of the intermediate layer is about 100 nm to 1,000 nm.
